(19) United States
(12) Patent Application Publication
(10) Pub. No.: US 2004/0094198 A1
(43) Pub. Date: May 20, 2004

(54) n-type Metal oxide semiconductor spectrally sensitized with a cationic spectral sensitizer

(75) Inventors: Paul Callant, Edegem (BE); Hieronymus Andriessen, Beerse (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 10/657,931

(22) Filed: Sep. 9, 2003

Related U.S. Application Data
(60) Provisional application No. 60/411,552, filed on Sep. 18, 2002.

(30) Foreign Application Priority Data
Sep. 12, 2002 (WO) PCT/EP02/10269

(51) Int. Cl. H01L 31/00

(52) U.S. Cl. 136/263; 136/256

(57) ABSTRACT

A layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on an n-type metal oxide semiconductor; and a process for preparing this layer configuration comprising the steps of: providing a layer of a nano-porous n-type metal oxide semiconductor with a band-gap of greater than 2.7 eV, adsorbing a coadsorber on the nano-porous n-type metal oxide semiconductor layer and adsorbing a cationic spectral sensitizer on the nano-porous n-type metal oxide semiconductor layer.

This application claims the benefit of U.S. Provisional Application No. 60/411,552 filed Sep. 18, 2002, which is incorporated by reference. In addition, this application claims the benefit of International Application No. PCT/EP 02/10269 filed Sep. 12, 2002, which is also incorporated by reference.

### FIELD OF THE INVENTION

The present invention relates to nano-porous n-type metal oxide semiconductor spectrally sensitized with a cationic spectral sensitizer.

### BACKGROUND OF THE INVENTION

The foundations of dye-sensitized semiconductors as an electrochemical means for light energy conversion were laid in the 1970's [see Gerischer, Photochem. Photobiol., volume 16, pages 243-260 (1972)] and developed into application of a dye-sensitized film to an electrode [see T. Miyasaka et al., Nature, volume 277, pages 638-640 (1979)]. Use of an aggregate of fine semiconductor particles having a large surface area available for dye adsorption had been proposed to bring about considerably improved light capturing efficiency, which has made it feasible to apply dye-sensitized semiconductor to a wet type solar cell. In particular, a wet type solar cell having a nano-porous film of dye-sensitized titanium dioxide semiconductor particles as a work electrode has been expected to surpass an amorphous silicon solar cell in conversion efficiency and cost. These fundamental techniques were disclosed in 1991 by Graetzel et al. in Nature, volume 353, pages 737-740 and in U.S. Pat. No. 4,927,721, U.S. Pat. No. 5,350,644 and JP-A 05-504023. In order to increase further the solar conversion efficiency of solar cells, it is important to increase the photocurrent photoefficiency. One approach is to improve the adsorption of dye sensitizers on the semiconductor layer.

EP-A 1 137 022 discloses semiconductor particles having a dye adsorbed thereby in the presence of an anionic sulfonic acid derivative, preferably represented by formula (I):

R₁—(Ar)ₘ-L₁-SO₃⁻M⁺ (I)

wherein R₁ represents a hydrogen atom or a substituted or unsubstituted alkyl group; Ar represents a substituted or unsubstituted arylene group; m represents 0 or 1; L₁ represents a single bond or a divalent linking group; and M⁺ represents a cation; provided that a combination of a hydrogen atom as R₁, 0 as m, and a single bond L₁ is excluded; or by formula (II):

R₂-Ph-O—(CH₂CH₂O)ₙ-L₂-SO₃⁻M⁺(II)

wherein R₂ represents a straight chain or branched alkyl group; Ph represents a phenylene group; n represents an integer of 0 to 50; L₂ represents a single bond, a substituted or unsubstituted alkylene group or a substituted or unsubstituted alkyleneoxy group; and M⁺ represents a cation.

JP-A 2001-024252 discloses a photo-electric conversion material containing a semiconductor sensitized with a pigment or dye whose adsorption thereon is assisted by a compound A represented by general formula (I): R-L-Z, wherein R is an optionally substituted alkyl, alkenyl or aryl group; L is a single bond or a divalent linking group; and Z is an acidic group (which dissociates a proton), or its alkali metal salt. Furthermore, the photo-electric conversion material may also contain a high molecular weight polymer B represented by general formula (II):

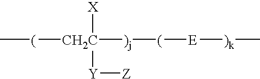

wherein X is a hydrogen atom or a C₁₋₄ alkyl group; Y is a single bond or a divalent linking group; E is a repeat unit derived from a compound with ethylenic unsaturation; Z is an acidic group (which dissociates a proton), or its alkali metal salt; and j,k are the weight composition ratio of the repeat units. Preferred acidic groups which dissociate a proton are carboxylic acid and sulfonic groups, although boric acid, phenolic and hydroxy groups are also mentioned. All the specific compounds according to formula (I) disclosed in JP-A 2001-024252 have a carboxy group as their acidic group which dissociates a proton and several compounds have more than one carboxy group.

In 2000 Rice et al. reported in the New Journal of Chemistry, volume 24, pages 651-652, that catechol was an efficient anchoring group for attachment of ruthenium-polypyridine photosensitizers to solar cells based on nanocrystalline titanium dioxide films, the formation of surface titanium-catecholate complexes in aqueous media having been previously reported by Borgias et al. [see Inorganic Chemistry, volume 23, 1009 (1984)] and Rodriguez et al. [see J. Colloidal and Interface Science, volume 177, pages 122-131 (1996)] and the formation of an interfacial charge transfer complex between catechol and titanium dioxide particles having been previously reported by Liu et al. [see J. Phys. Chem. B, volume 103, pages 2480-2486 (1999)]. Moreover, in 1993 Redmond et al. had established that the adsorption of pyrocatechol on the surface of a transparent nanocrystalline titanium dioxide film altered the dependence of the rate constant for accumulation on the initially applied potential in a manner consistent with energetic promotion of the intraband surface state, associated with incompletely coordinated Ti atoms at the surface of the nanocrystalline titanium dioxide film, into the conduction band.

A critical feature of photovoltaic devices based on nano-porous titanium dioxide is their spectral sensitization, which in large measure determines their efficiency. Organic metal complex dyes (preferably including ruthenium) usually show a very fast electron injection in the titanium dioxide semiconductor upon light excitation. Pure anionic organic dye compounds (e.g. merocyanines) also exhibit very fast electron injection in the TiO₂ semiconductor upon light excitation. Spectral sensitization of titanium dioxide semiconductors with cationic dye sensitizers is, to our knowledge, unknown.

There is therefore a need for enhanced spectral dye sensitization of n-type metal oxide semiconductors and for methods to achieve enhanced spectral sensitization of nano-porous n-type metal oxide semiconductors with dyes. Furthermore, there is also a need for a means of using cationic dye sensitizers for the sensitization of n-type metal oxide semiconductors.

### ASPECTS OF THE INVENTION

It is therefore an aspect of the present invention to provide a layer configuration in which a n-type metal oxide semiconductor layer is efficiently spectrally sensitized with a cationic dye sensitizer.

It is a further aspect of the present invention to provide a process for achieving efficient spectral sensitization of a n-type metal oxide semiconductor with a cationic dye sensitizer.

It is also an aspect of the present invention to provide a cationic dye-sensitized photovoltaic device which achieves a high short circuit current.

It is also an aspect of the present invention to provide a cationic dye-sensitized solar cell which achieves a high conversion efficiency.

Further aspects and advantages of the invention will become apparent from the description hereinafter.

### SUMMARY OF THE INVENTION

It has been surprisingly found that by coadsorbing cationic dye sensitizers with certain ortho-dihydroxy-benzene compounds, such as 3,4,5-trihydroxy-benzonitrile and 3,4-dihydroxy-benzonitrile, on nano-porous n-type metal oxide semiconductors, that the adsorption of the cationic dyes is enhanced together with their sensitization efficiency. This can be achieved by first adsorbing the ortho-dihydroxy-benzene compound and then adsorbing the cationic dye sensitizer or by adsorbing the ortho-dihydroxy-benzene compound and the cationic dye sensitizer simultaneously.

Aspects of the present invention are realized by a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

Aspects of the present invention are also realized by a photovoltaic device comprising the above-mentioned layer configuration.

Aspects of the present invention are also realized by a solar cell comprising the above-mentioned layer configuration.

Aspects of the present invention are also realized by a process for preparing the above-mentioned layer configuration comprising the steps of: providing a layer of a nano-porous n-type metal oxide semiconductor with a band-gap of greater than 2.7 eV, adsorbing the coadsorber on the nano-porous n-type metal oxide semiconductor layer and adsorbing a cationic spectral sensitizer on the n-type metal oxide semiconductor layer.

Preferred embodiments are disclosed in the dependent claims.

### DETAILED DESCRIPTION OF THE INVENTION

### Definitions

The term nano-porous metal oxide semiconductor means a metal oxide semiconductor having pores with a size of 100 nm or less and having an internal surface area of at least 20 m²/g and not more than 300 m²/g.

The term anionic spectral sensitizer means a dye with an overall negative charge having spectral sensitizing properties, such as cyanine dyes with at least two covalently-bonded acidic group either as a free acid or as a salt and merocyanine dyes with at least one covalently-bonded acidic group either as a free acid or as a salt. Covalently bonded acidic groups include a hydroxy group on an aromatic ring system and sulpho [—SO₃⁻], sulphato [—O—SO₃⁻], carboxy [—CO₂⁻] and phosphoric acid groups. Anionic dyes exhibit an ionic interaction with positively charged sites on surfaces, such as on certain natural and artificial fibres.

The term cationic spectral sensitizer means a dye with an overall positive charge having spectral sensitizing properties, such as merocyanine dye with at least one covalently-bonded positively charged group, such as a quaternary ammonium group or a ternary sulfonium group, and cyanine dyes. Cationic dyes exhibit an ionic interaction with negatively charged sites on surfaces, such as on certain natural and artificial fibres.

The term ortho-dihydroxy-benzene compound includes 1,2-dihydroxybenzene, also known as cathechol, and substituted ortho-dihydroxy-benzene compounds, such substitution also including carbocyclic and heterocyclic rings systems annelated (i.e. sharing two carbon atoms) with a ortho-dihydroxy-benzene nucleus for example aromatic and heteroaromatic ring systems.

The term alkyl means all variants possible for each number of carbon atoms in the alkyl group i.e. for three carbon atoms: n-propyl and isopropyl; for four carbon atoms: n-butyl, isobutyl and tertiary-butyl; for five carbon atoms: n-pentyl, 1,1-dimethyl-propyl, 2,2-dimethylpropyl and 2-methyl-butyl etc.

The term “support” means a “self-supporting material” so as to distinguish it from a “layer” which may be coated on a support, but which is itself not self-supporting. It also includes any treatment necessary for, or layer applied to aid, adhesion to the support.

The term continuous layer refers to a layer in a single plane covering the whole area of the support and not necessarily in direct contact with the support.

The term non-continuous layer refers to a layer in a single plane not covering the whole area of the support and not necessarily in direct contact with the support.

### Nano-Porous Metal Oxide Semiconductor

Aspects of the present invention are provided by a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

According to a first embodiment of the layer configuration, according to the present invention, the n-type metal oxide semiconductor is selected from the group consisting of titanium oxides, tin oxides, niobium oxides, tantalum oxides and zinc oxides.

According to a second embodiment of the layer configuration, according to the present invention, the n-type metal oxide semiconductor is titanium dioxide.

For efficient solar cells, the coating of the nano-porous TiO₂ should be between 8 and 12 μm in order to have sufficient light absorption for generating power conversion efficiencies up to 5 to 8%. The thicker the titanium dioxide coating, the longer the pathway for the charges (electrons) have to be transported to the charge collecting electrode and the greater the probability of recombination occurring with resultant power conversion efficiency loss. In order to circumvent this problem smaller titanium dioxide nano-particles can be used, having a larger specific surface and hence enabling thinner layers to be realized with the same light absorbance values. In this way, photovoltaic cells with higher efficiencies can be obtained due to the fact that the probability of recombination is reduced due to the path traversed by the electrons to the charge collecting electrode being shorter.

The metal oxide semiconductor nano-particles with a band-gap of greater than 2.7 eV used in the process, according to the present invention, can be prepared by wet precipitation and non-wet-precipitation processes. Non-wet-precipitation processes include such processes as the flame pyrolysis process operated by DEGUSSA. Titanium dioxide nano-particles produced according to wet-chemical process are commercially available from SOLARONIX SA as Ti-Nanoxide™ T, a nano-sized titanium dioxide with a mean particle size of 13 nm and a specific surface of 120 m²/g, and Ti-Nanoxide™ HT, a nano-sized titanium dioxide with a mean particle size 9 nm and specific surface of 165 m²/g, which are often used as n-type semi-conductor nano-particles in making Graetzel-type photovoltaic cells, or can be readily synthesized using fairly straightforward precipitation techniques as disclosed in 1997 by Barbe et al. in the Journal of the American Ceramic Society, volume 80 (12), pages 3157-3171, herein incorporated by reference.

According to a third embodiment of the layer configuration, according to the present invention, the metal oxide is titanium dioxide prepared by a non-wet-precipitation process.

### Cationic Spectral Sensitizers

Aspects of the present invention are provided by a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

According to a fourth embodiment of the layer configuration, according to the present invention, the cationic spectral sensitizer is a cyanine dye.

Cationic spectral sensitizers suitable for use in the present invention include:

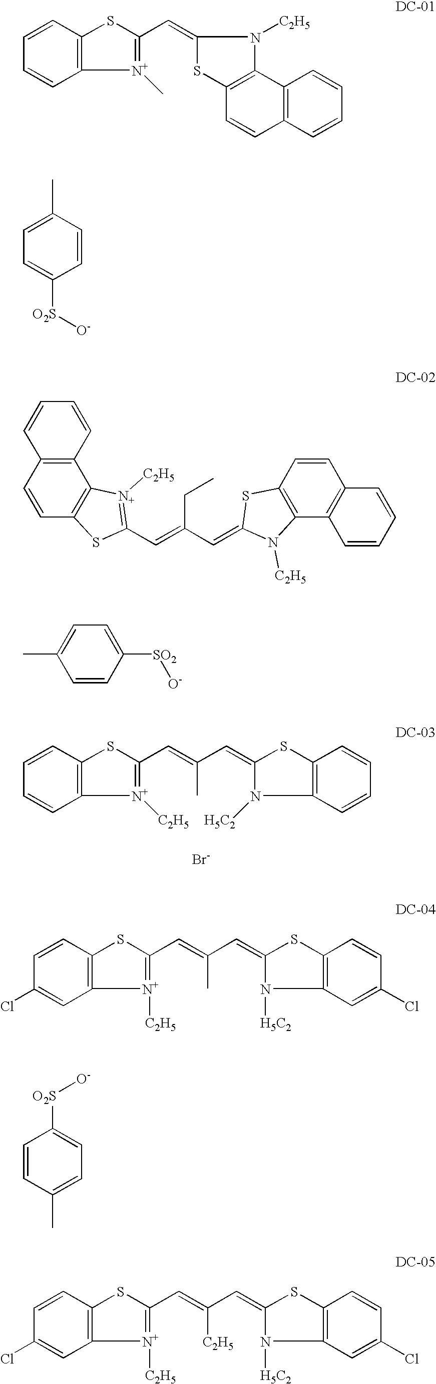

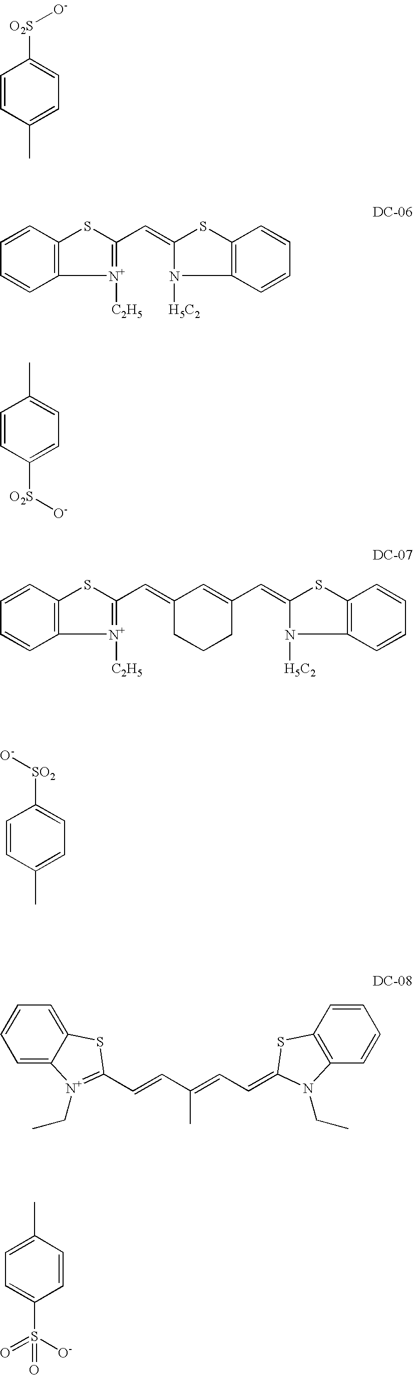

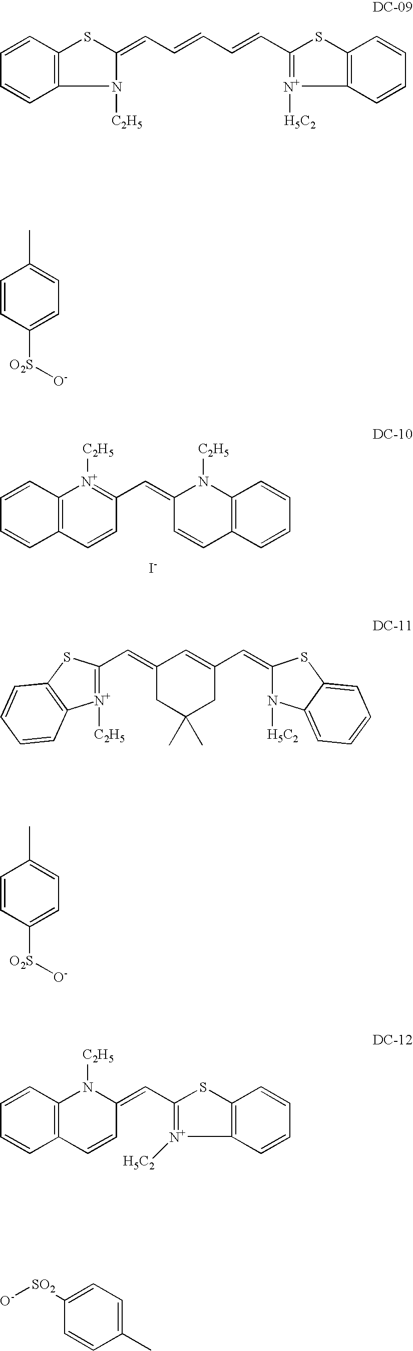

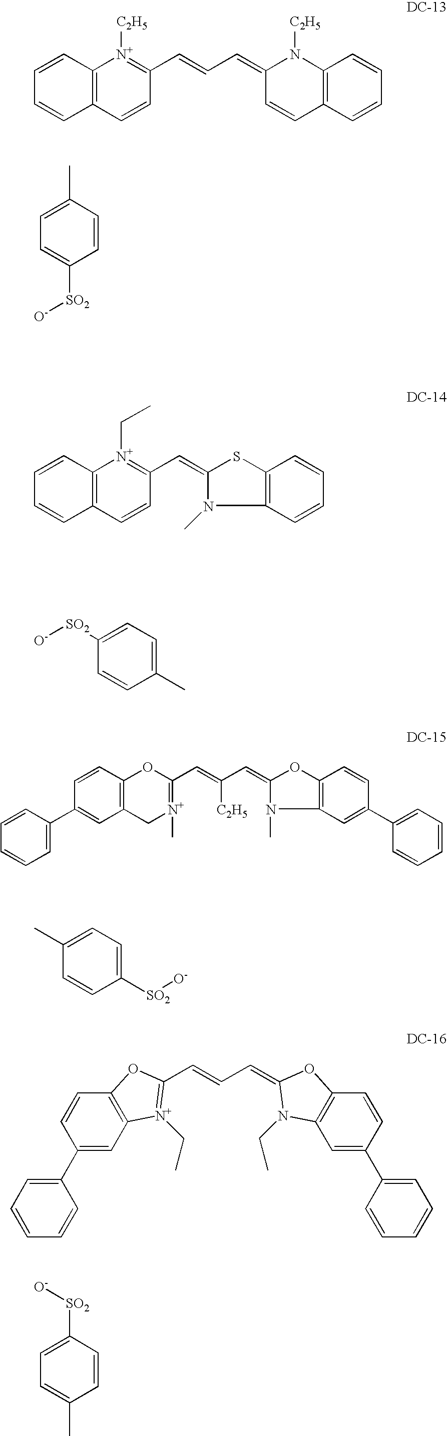

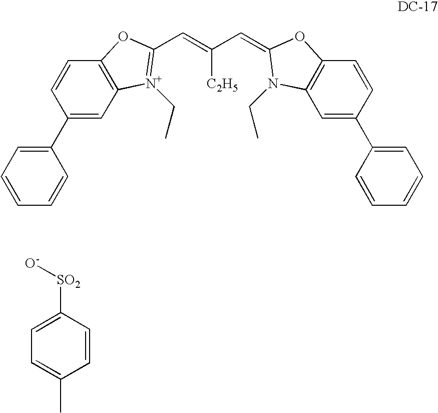

### Coadsorber

Aspects of the present invention are provided by a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

According to a fifth embodiment of the layer configuration, according to the present invention, the coadsorber is an ortho-dihydroxy-benzene compound.

According to a sixth embodiment of the layer configuration, according to the present invention, the coadsorber is an ortho-dihydroxy-benzene compound with a group having a Hammett σ value of at least 0.60 and below 1.00.

According to a seventh embodiment of the layer configuration, according to the present invention, the coadsorber is an ortho-dihydroxy-benzene compound with a group having a Hammett σ value of at least 0.60 and below 1.00, wherein the ortho-dihydroxy-benzene compound has the ortho-dihydroxy-groups and the group having a Hammett σ value of at least 0.60 and below 1.00 on the same benzene ring.

According to an eighth embodiment of the layer configuration, according to the present invention, the coadsorber is an ortho-dihydroxy-benzene compound with a nitrile group substituted on the same benzene ring as the ortho-dihydroxy-groups.

According to a ninth embodiment of the layer configuration, according to the present invention, the coadsorber is selected from the group consisting of 2,3-dihydroxy-benzonitrile, 3,4-dihydroxy-benzonitrile, 3,4,5-trihydroxy-benzonitrile, 3,4-dihydroxy-4′-cyano-benzophenone, 4-nitro-catechol, (3,4-dihydroxy-phenyl)methyl-sulphone, 1,2-dihydroxy-anthraquinone, 3,4-dihydroxy-anthraquinone-2-sulphonic acid, 4,5-dihydroxy-benzene-1,3-disulphonic acid, 6,7-dihydroxy-naphthalene-2-sulphonic acid, 3,4-dihydroxy-benzoic acid and catechol.

According to a tenth embodiment of the layer configuration, according to the present invention, the coadsorber is selected from the group consisting of 3,4-dihydroxy-benzonitrile, 3,4,5-trihydroxy-benzonitrile, 1,2-dihydroxy-anthraquinone, (3,4-dihydroxy-phenyl)methyl-sulphone, 4,5-dihydroxy-benzene-1,3disulphonic acid and catechol.

Coadsorbers suitable for use in the present invention include:

CA-01 3,4-dihydroxy-benzonitrile

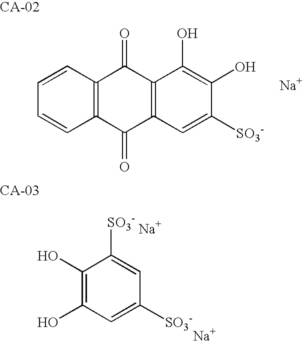

CA-04 1,2-dihydroxy-anthraquinone

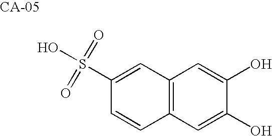

CA-06 ethyl 3,4-dihydroxybenzoate

CA-07 3,4-dihydroxy-benzophenone

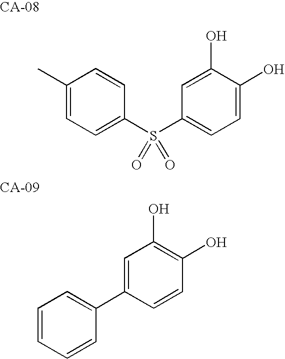

CA-10 2,3-dihydroxy-benzonitrile

CA-11 3,4,5-trihydroxy-benzonitrile

CA-12 3,4-dihydroxy-4′-cyano-benzophenone

CA-13 4-nitro-catechol

CA-14 (3,4-dihydroxy-phenyl)methylsulphone

CA-15 3,4-dihydroxy-benzoic acid

CA-16 catechol

### Process for Preparing a Layer Configuration

Aspects of the present invention are realized by a process for preparing a layer configuration, according to the present invention, comprising the steps of: providing a layer of a nano-porous n-type metal oxide semiconductor with a band-gap of greater than 2.7 eV, adsorbing a coadsorber on the nano-porous n-type metal oxide semiconductor layer and adsorbing a cationic spectral sensitizer on the nano-porous n-type metal oxide semiconductor layer.

According to a first embodiment of the process for preparing a layer configuration, according to the present invention, the adsorption of the cationic spectral sensitizer on the nano-porous n-type metal oxide semiconductor layer is carried out simultaneously with the adsorption of the coadsorber on the nano-porous n-type metal oxide semiconductor layer. When applied from the same solution it is possible that complex formation between the coadsorber and the cationic spectral sensitizer takes place before adsorption on the nano-porous n-type metal oxide semiconductor layer i.e. that a complex is adsorbed rather than the two components individually.

According to a second embodiment of the process for preparing a layer configuration, according to the present invention, the adsorption of the cationic spectral sensitizer on the nano-porous n-type metal oxide semiconductor layer is carried out after the adsorption of the coadsorber on the nano-porous n-type metal oxide semiconductor layer.

### Support

Supports for use according to the present invention include polymeric films, silicon, ceramics, oxides, glass, polymeric film reinforced glass, glass/plastic laminates, metal/plastic laminates, paper and laminated paper, optionally treated, provided with a subbing layer or other adhesion promoting means to aid adhesion to the light-exposure differentiable element. Suitable polymeric films are poly(ethylene terephthalate), poly(ethylene naphthalate), polystyrene, polyethersulphone, polycarbonate, polyacrylate, polyamide, polyimides, cellulose triacetate, polyolefins and poly(vinylchloride), optionally treated by corona discharge or glow discharge or provided with a subbing layer.

### Photovoltaic Devices

Aspects of the present invention are also realized by a photovoltaic device comprising the layer configuration, according to the present invention, or produced according to the process, according to the present invention.

Photovoltaic devices incorporating the spectrally sensitized nano-porous n-type metal oxide semiconductor, according to the present invention, can be of two types: the regenerative type which converts light into electrical power leaving no net chemical change behind in which current-carrying electrons are transported to the anode and the external circuit and the holes are transported to the cathode where they are oxidized by the electrons from the external circuit and the photosynthetic type in which there are two redox systems one reacting with the holes at the surface of the semiconductor electrode and one reacting with the electrons entering the counter-electrode, for example, water is oxidized to oxygen at the semiconductor photoanode and reduced to hydrogen at the cathode. In the case of the regenerative type of photovoltaic cell, as exemplified by the Graetzel cell, the hole transporting medium may be a liquid electrolyte supporting a redox reaction, a gel electrolyte supporting a redox reaction, an organic hole transporting material, which may be a low molecular weight material such as 2,2′,7,7′-tetrakis(N,N-di-p-methoxyphenyl-amine)9,9′-spirobifluorene (OMeTAD) or triphenylamine compounds or a polymer such as PPV-derivatives, poly(N-vinylcarbazole) etc., or inorganic semiconductors such as CuI, CuSCN etc. The charge transporting process can be ionic as, for example, in the case of a liquid electrolyte or gel electrolyte or electronic as, for example, in the case of organic or inorganic hole transporting materials.

Such regenerative photovoltaic devices can have a variety of internal structures in conformity with the end use. Conceivable forms are roughly divided into two types: structures which receive light from both sides and those which receive light from one side. An example of the former is a structure made up of a transparently conductive layer e.g. an ITO-layer or a PEDOT/PSS-containing layer and a transparent counter electrode electrically conductive layer e.g. an ITO-layer or a PEDOT/PSS-containing layer having interposed therebetween a photosensitive layer and a charge transporting layer. Such devices preferably have their sides sealed with a polymer, an adhesive etc. to prevent deterioration or volatilization of the inside substances. The external circuit connected to the electrically-conductive substrate and the counter electrode via the respective leads is well-known.

Alternatively the spectrally sensitized nano-porous n-type metal oxide semiconductor, according to the present invention, can be incorporated in hybrid photovoltaic compositions such as described in 1991 by Graetzel et al. in Nature, volume 353, pages 737-740, in 1998 by U. Bach et al. [see Nature, volume 395, pages 583-585 (1998)] and in 2002 by W. U. Huynh et al. [see Science, volume 295, pages 2425-2427 (2002)]. In all these cases, at least one of the components (light absorber, electron transporter or hole transporter) is inorganic (e.g. nano-TiO₂ as electron transporter, CdSe as light absorber and electron transporter) and at least one of the components is organic (e.g. triphenylamine as hole transporter or poly(3-hexylthiophene) as hole transporter).

### Industrial Application

Layer configurations, according to the present invention, can be used in photovoltaic devices and solar cells.

The invention is illustrated hereinafter by way of reference and invention light emitting devices. The percentages and ratios given in these examples are by weight unless otherwise indicated.

Anionic spectral sensitizers used in the comparative experiments:

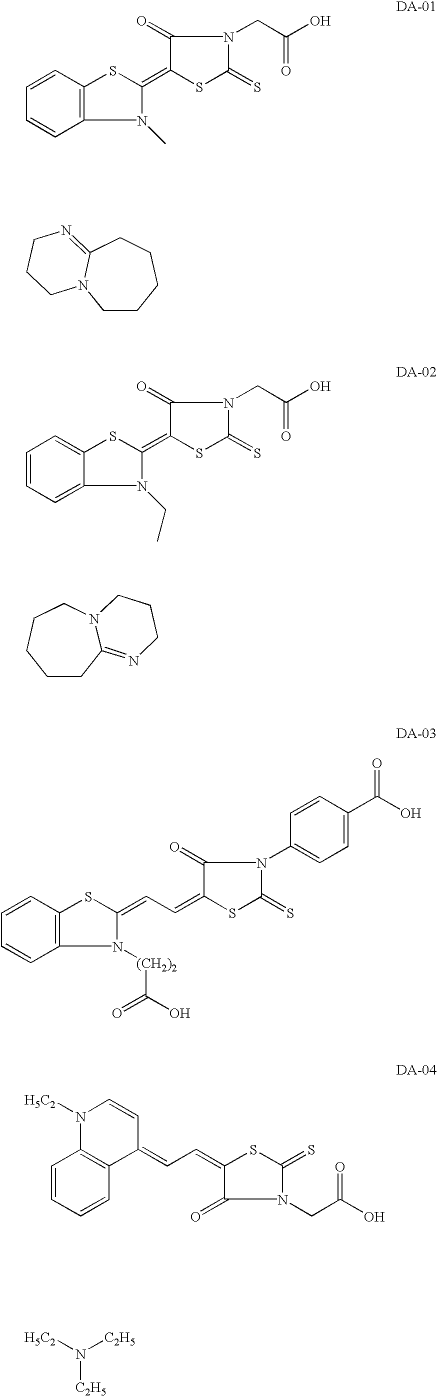

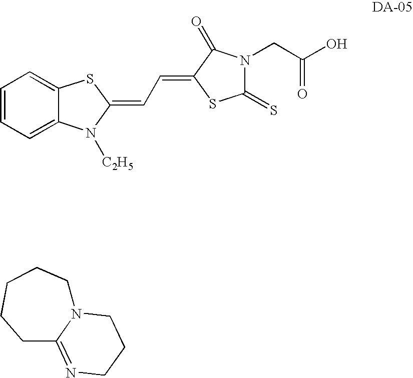

### EXAMPLE 1

### Adsorption of Dyes on a Nano-Porous TiO₂ Layer

A glass substrate (FLACHGLAS AG) was ultrasonically cleaned in ethanol for 5 minutes and then dried. A layer of a nano-TiO2 dispersion (Ti-nanoxide HT from Solaronix SA) was applied to the glass substrate using a doctor blade coater. This titanium dioxide-coated glass was heated to 450° C. for 30 minutes. This results in a highly transparent nano-porous TiO₂ layer. A dry layer thickness of 1.5 μm, 3 μm or 5 μm, as verified by laserprofilometry (DEKTRAK™ profilometer), mechanically with a diamond-tipped probe (Perthometer) and interferometry, was obtained depending on the doctor blade knife used.

After this sintering step, the titanium dioxide-coated glass plates were cooled to 150° C. by placing it on a hot plate at 150° C. for 10 minutes and then immediately immersed in a dye-containing solution optionally containing an ortho-dihydroxy-benzene compound where they remained for 15 to 17 hours. After immersion in the dye solution, the titanium dioxide layers were rinsed with acetonitrile to remove non-adsorbed dye and then dried at 50° C. for several mins.

Absorption spectra between 200 and 800 nm were obtained using a Hewlett-Packard diode-array spectrophotometer HP 8452A. The results are given in Table 1 for adsorption of the cationic dyes and reference spectra of the dyes in acetonitrile.

TABLE 1

| Comparative | | λₘₐₓ of | λₘₐₓ of dyed | |
|---|---|---|---|---|
| experiment | Cationic | dye solution | TiO₂-layer | Absorbance at λₘₐₓ |
| nr | dye | [nm] | [nm] | of dyed TiO₂-layer |
| 1 | DC-01 | 440 | — | 0.4 (color lost) |
| 2 | DC-02 | 586 | — | — |
| 3 | DC-03 | 543 | — | — |
| 4 | DC-04 | 548 | — | — |
| 5 | DC-05 | 548 | — | — |
| 6 | DC-06 | 426 | — | 0.2 (color lost) |
| 7 | DC-07 | 644 | — | 0.6 (color lost) |
| 8 | DC-08 | 650 | — | 0.8 (color lost) |
| 9 | DC-09 | 654 | — | 0.6 (color lost) |
| 10 | DC-10 | 524 | — | 0.6 (color lost) |
| 11 | DC-11 | 648 | — | 0.7 (color lost) |
| 12 | DC-12 | 484 | — | 0.7 (color lost) |
| 13 | DC-13 | 604 | — | 0.4 (color lost) |
| 14 | DC-14 | 484 | — | 0.18 (color lost) |
| 15 | DC-15 | 500 | — | — |
| 16 | DC-16 | 498 | — | — |
| 17 | DC-17 | 502 | — | — |

Immersion of the freshly sintered titanium dioxide layers in 2×10⁻⁴ M solutions of the cationic dyes, DC-01 to DC-17, in acetonitrile for 15 to 17 hours, resulted in no detectable dye adsorption after washing with acetonitrile.

The absorption results for coadsorption of the cationic dyes with an ortho-dihydroxy-benzene compound according to the present invention are given in Table 2.

TABLE 2

| | | | λₘₐₓ | | |
|---|---|---|---|---|---|
| | | | of | | |
| | | | cationic | λₘₐₓ | Absorbance |
| Invention | | | dye | of dyed | at |
| experiment | Cationic | | solution | TiO₂-layer | λₘₐₓ of dyed |
| nr. | dye | Coadsorber | [nm] | [nm] | TiO₂-layer |
| 1 | DC-01 | CA-01 | 440 | 424 | 0.77 |
| 2 | DC-02 | CA-01 | 586 | 597 | 0.38 |
| 3 | DC-03 | CA-01 | 543 | 549 | 0.24 |
| 4 | DC-04 | CA-01 | 548 | 554 | 0.24 |
| 5 | DC-05 | CA-01 | 548 | 559 | 0.17 |
| 6 | DC-06 | CA-01 | 426 | 426 | 0.72 |
| 7 | DC-07 | CA-01 | 644 | 663 | 1.1 |
| 8 | DC-08 | CA-01 | 650 | 650 | 1.0 |
| 9 | DC-09 | CA-01 | 654 | 654 | 1.0 |
| 10 | DC-10 | CA-01 | 524 | 526 | 0.67 |
| 11 | DC-11 | CA-01 | 648 | 648 | 0.65 |
| 12 | DC-12 | CA-01 | 484 | 486 | 0.41 |
| 13 | DC-13 | CA-01 | 604 | 608 | 0.90 |
| 14 | DC-14 | CA-01 | 484 | 456 | 0.39 |
| 15 | DC-15 | CA-01 | 500 | 500 | 0.86 |
| 16 | DC-16 | CA-01 | 498 | 502 | 0.85 |
| 17 | DC-17 | CA-01 | 502 | 508 | 0.71 |
| 18 | DC-02 | CA-02 | 586 | 586 | 0.33# |
| 19 | DC-02 | CA-03 | 586 | 594 | 0.48 |
| 20 | DC-02 | CA-04 | 586 | 590 | 0.20 |
| 21 | DC-03 | CA-04 | 543 | 553 | 0.40* |
| 22 | DC-04 | CA-04 | 550 | 564 | 0.35* |
| 23 | DC-05 | CA-04 | 583 | 560 | 0.32* |
| 24 | DC-02 | CA-05 | 586 | 586 | 0.25 |
| 25 | DC-02 | CA-06 | 586 | 586 | 0.19 |
| 26 | DC-03 | CA-06 | 543 | 550 | 0.17 |
| 27 | DC-04 | CA-06 | 548 | 551 | 0.15 |
| 28 | DC-02 | CA-07 | 586 | 586 | 0.14 |
| 29 | DC-03 | CA-07 | 543 | 550 | 0.26 |
| 30 | DC-04 | CA-07 | 548 | 553 | 0.18 |
| 31 | DC-05 | CA-07 | 548 | 552 | 0.23 |
| 32 | DC-02 | CA-08 | 586 | 586 | 0.31 |
| 33 | DC-03 | CA-08 | 543 | 550 | 0.28 |
| 34 | DC-04 | CA-08 | 548 | 553 | 0.28 |
| 35 | DC-05 | CA-08 | 548 | 552 | 0.25 |
| 36 | DC-02 | CA-09 | 586 | 586 | 0.26 |
| 37 | DC-03 | CA-09 | 543 | 550 | 0.27 |
| 38 | DC-04 | CA-09 | 548 | 553 | 0.22 |
| 39 | DC-01 | CA-11 | 440 | 422 | 1.47 |
| 40 | DC-02 | CA-11 | 576 | 592 | 0.96 |
| 41 | DC-15 | CA-11 | 500 | 516 | 1.46 |
| 42 | DC-01 | CA-14 | 440 | 416 | 0.69 |
| 43 | DC-15 | CA-14 | 500 | 505 | 0.35 |
| 44 | DC-01 | CA-15 | 440 | 419 | 0.34 |
| 45 | DC-15 | CA-15 | 500 | 508 | 0.17 |
| 46 | DC-01 | CA-16 | 440 | 417 | 0.53 |
| 47 | DC-02 | CA-16 | 576 | 580 | 0.20 |
| 48 | DC-15 | CA-16 | 500 | 504 | 0.21 |

#corrected for absorbance of CA-02 on titanium dioxide
*corrected for absorbance of CA-04 on titanium dioxide

Immersion of the freshly sintered titanium dioxide layers in acetonitrile solutions 2×10⁻⁴ M in cationic dye (DC-01 to DC-17) and 2×10⁻⁴ M in coadsorber compounds CA-01 to CA-09, CA-11, C-14 to C-16 respectively resulted in detectable dye adsorption. Particularly strong adsorption was observed with cationic dyes with coadsorbers CA-01, CA-03, CA-04, CA-11, CA-14 and CA-15.

It should also be noted that no difference in dye adsorption was observed when coadsorber CA-01 was adsorbed on the titanium dioxide layer from a 2×10⁻⁴ M acetonitrile solution of CA-01 by immersion for 15 to 17 hours as described for the dye solutions, washed with acetonitrile, dried at 50° C. for several minutes before immersion for 15 to 17 hours in a 2×10⁻⁴ M acetonitrile solution of DC-01, DC-02 and DC-11, washing with acetonitrile and finally drying at 50° C. for several minutes.

By way of reference five anionic dyes were adsorbed on the TiO₂-surface (1.5 μm thickness): DA-01, DA-02, DA-03, DC-04 and DC-05 using the same procedure as for the cationic dyes. The results of these adsorption experiments are shown in Table 4.

It can be concluded from the results given in Table 4, that comparable light absorption can be attained on nano-porous titanium dioxide with cationic spectral sensitizers in association with the coadsorber, according to the present invention, to that attainable with anionic spectral sensitizers.

TABLE 4

| Comparative | | λₘₐₓ of | λₘₐₓ of dyed | Absorbance at |
|---|---|---|---|---|
| experiment | Anionic | anionic dye | TiO₂-layer | λₘₐₓ of |
| nr | dye | solution [nm] | [nm] | dyed TiO₂-layer |
| 18 | DA-1 | 430 | 420 | 1.75 |
| 19 | DA-2 | 426 | 420 | 1.45 |
| 20 | DA-3 | 500 | 500 | 1.63 |
| 21 | DA-4 | 610 | 580 | 1.95 |
| 22 | DA-5 | 520 | 500 | 1.45 |

### EXAMPLE 2

### Influence of Molar Ratio of Coadsorber to Cationic Spectral Sensitzer on Absorbance of Adsorbed Spectral Sensitizer on TiO₂

Invention experiments 41 to 50 were carried out as described for Invention experiments 16 and 17 except that the concentrations of DC-16, DC-17 and CA-01 were varied as given in Table 5.

TABLE 5

| | Cationic dye | | | |
|---|---|---|---|---|
| | | concentration | | |
| | | [M] in | CA-01 | Absorbance |
| Invention | | adsorbing | concentration in | at λₘₐₓ |
| experiment | | CH₃CN | adsorbing CH₃CN | of dyed |
| nr. | type | solution | solution [M] | TiO₂-layer |
| 41 | DC-16 | 1.5 × 10⁻⁴ | 0.5 × 10⁻⁴ | 0.93 |
| 42 | DC-16 | 1.0 × 10⁻⁴ | 1.0 × 10⁻⁴ | 0.88 |
| 43 | DC-16 | 0.66 × 10⁻⁴ | 1.34 × 10⁻⁴ | 0.85 |
| 44 | DC-16 | 0.5 × 10⁻⁴ | 1.5 × 10⁻⁴ | 0.83 |
| 45 | DC-16 | 0.2 × 10⁻⁴ | 1.8 × 10⁻⁴ | 0.61 |
| 46 | DC-17 | 1.5 × 10⁻⁴ | 0.5 × 10⁻⁴ | 0.93 |
| 47 | DC-17 | 1.0 × 10⁻⁴ | 1.0 × 10⁻⁴ | 0.87 |
| 48 | DC-17 | 0.66 × 10⁻⁴ | 1.34 × 10⁻⁴ | 0.80 |
| 49 | DC-17 | 0.5 × 10⁻⁴ | 1.5 × 10⁻⁴ | 0.71 |
| 50 | DC-17 | 0.2 × 10⁻⁴ | 1.8 × 10⁻⁴ | 0.52 |

The results given in Table 5 show that the adsorption of cationic dyes in the presence of CA-01 increased strongly with CA-01 concentration for both DC-16 and DC-17 i.e. a higher absorbance on titanium dioxide was observed at a dye concentration of 5×10⁻⁵ M and a CA-01 concentration of 1.5×10⁻⁴ M than at a dye concentration of 1×10⁻⁴ M and a CA-01 concentration of 1×10⁻⁴ M.

### EXAMPLE 3

### Evaluation in Photovoltaic Devices

Photovoltaic devices 1 to 8 were prepared as follows:

### Preparation of the Front Electrode

A glass plate (2×7 cm²) coated with conductive SnO₂:F (Pilkington TEC15/3) with a surface conductivity of ca 15 Ohm/square was ultrasonically cleaned in isopropanol for 5 minutes and then dried.

The electrode was taped off at the borders and was doctor blade-coated in the middle (0.7×4.5 cm²) with the above-described Solaronix disperion of TiO₂ to give layer thicknesses after sintering of 1.8 or 5 μm to ensure comparable optical absorbances of the cells. The sintering procedure and cationic spectral sensitizer adsorption procedure in the presence of a coadsorber were as described for EXAMPLE 1. The front electrode was thereby produced, which was immediately used in assembling the cell.

### Cell Assembly

The back electrode (consisting of SnO₂:F glass (Pilkington TEC15/3) evaporated with platinum to catalyse the reduction of the electrolyte) was sealed together with the front electrode with two pre-patterned layers of Surlyn® (DuPont) (2×7 cm² where in the middle 1×6 cm² had been removed) in between. This was performed at a temperature just above 100° C. on a hotplate. As soon as the sealing was completed, the cell was cooled to 25° C. and electrolyte was added through holes in the counter electrode. The electrolyte used was a solution of 0.5 M LiI, 0.05 M I₂ and 0.4 M t-butylpyridine in acetonitrile and was injected into the cell during cell assembly. The holes were then sealed with Surlyn® and a thin piece of glass. Conductive tape was attached on both long sides of the cell to collect the electricity during measurement.

### Device Characterisation

The cell was irradiated with a Steuernagel Solar Constant 575 solar simulator with a metal halide 1 AM light source. The simulator was adjusted to about 1 sunequivalent. The generated electricity was recorded with a Keithley electrometer (Type 2400 SMU). The open circuit voltage (V_{oc}), short circuit current density (I_{sc}) and Fill Factor (FF) of the photocell calculated from the quantity of electricity generated are shown in table 6.

TABLE 6

| | | | TiO₂ | | Absorbance | | | |
|---|---|---|---|---|---|---|---|---|
| Device | | | thickness | λₘₐₓ | at | I_{SC} | V_{OC} | |
| nr. | Dye | Coadsorber | [μm] | [nm] | λₘₐₓ | [mA/cm²] | [V] | FF |
| 1 (comp.) | DA-01 | — | 1.8 | 420 | 1.20 | 1.65 | 0.440 | 0.49 |
| 2 (comp.) | DA-02 | — | 1.8 | 420 | 1.30 | 1.8 | 0.485 | 0.48 |
| 3 (comp.) | DA-03 | — | 1.8 | 500 | 2.22 | 1.25 | 0.507 | 0.56 |
| 4 (comp.) | DA-04 | — | 1.8 | 580 | 1.98 | 0.25 | 0.132 | 0.40 |
| 5 (comp.) | DA-05 | — | 1.8 | 500 | 1.15 | 1.2 | 0.397 | 0.51 |
| 6 (inv.) | DC-01 | CA-01 | 5.0 | 440 | 2.20 | 1.9 | 0.525 | 0.59 |
| 7 (inv.) | DC-02 | CA-01 | 5.0 | 590 | 1.85 | 1.7 | 0.515 | 0.59 |
| 8 (inv.) | DC-02 | CA-02 | 5.0 | 590 | 1.30 | 0.6 | 0.400 | 0.54 |

The results in Table 6 show that comparable short circuit currents [I_{SC}] can be realized with cationic dye sensitization in the presence of a coadsorber as can be obtained with anionic dye sensitization, especially if the dye absorbs in the red region of the visible spectrum.

### EXAMPLE 4

### Spectral Sensitization with Mixtures of Cationic Spectral Sensitizers

To broaden the spectral response of photovoltaic devices based on spectral sensitization of nano-porous titanium dioxide with cationic spectral sensitizers with a coadsorber capable of enhancing the adsorption thereof, a mixture of cationic dyes was used together with the coadsorber CA-01.

Photovoltaic cells were prepared as described in EXAMPLE 3 with the cationic spectral sensitizers separately and with a mixtures of the cationic spectral sensitizers. For these experiments Degussa P25 TiO₂ nano-colloid, a nano-titanium dioxide produced by a non-wet-precipitation process i.e. by flame pyrolysis, was used instead of the Ti-nanoxide HT from Solaronix, a nano-titanium dioxide produced by a wet-precipitation process, 5 g of Degussa P25 being added to 15 mL of water with 1 mL of Triton X-100 being subsequently added. The resulting titanium dioxide colloidal dispersion was cooled in ice and ultrasonically treated for 5 minutes. This titanium dioxide colloidal dispersion was then further used as described above for the Ti-nanoxide HT dispersion.

The dye adsorption was carried out with a cationic spectral sensitizer concentration of 1×10⁻⁴ M and a CA-1 concentration of 1×10⁻⁴ M for the three cationic spectral sensitizers and with a mixture of 0.5×10⁻⁴ M CA-01, 0.3×10⁻⁴ M DC-01, 0.7×10⁻⁵ M DC-15 and 0.5×10⁻⁴M DC-02. If equal amounts of the three dyes were used, an inhomogeneous spectrum resulted due to the differences in adsorption strength of the cationic spectral sensitizers. The relative amounts of the dyes were therefore adapted to realize a homogeneous absorption throughout the visible spectrum.

The thereby prepared photovoltaic cells were irradiated with a Xenon Arc Discharge lamp with a power of 100 mW/cm². The current generated was recorded with a Keithley electrometer (Type 2420). The open circuit voltage (V_{oc}), short circuit current density (I_{sc}) and Fill Factor (FF) of the photocell as calculated from the quality of generated current are given in Table 7.

TABLE 7

| | | | TiO₂ | | Absorbance | | | |
|---|---|---|---|---|---|---|---|---|
| Device | | | thickness | λₘₐₓ | at | I_{SC} | V_{OC} | |
| nr. | Dye | Coadsorber | [μm] | [nm] | λₘₐₓ | [mA/cm²] | [V] | FF |
| 9 | DC-01 | CA-01 | 2.0 | 430 | 1.08 | 1.71 | 0.470 | 0.41 |
| 10 | DC-15 | CA-01 | 2.0 | 508 | 0.92 | 1.93 | 0.570 | 0.57 |
| 11 | DC-02 | CA-01 | 2.0 | 588 | 0.98 | 1.35 | 0.460 | 0.51 |
| 12 | DC-01, | CA-01 | 2.0 | 430 | 0.45 | 1.96 | 0.600 | 0.38 |
| | DC-15, | | | 508 | 0.50 | | | |
| | DC-02 | | | 588 | 0.49 | | | |

As can be seen from Table 7, although the absorbance values for the dye mixture are half of the values for the dyes adsorbed separately, comparable or higher short circuit current values were obtained due to the broader spectral response.

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

Having described in detail preferred embodiments of the current invention, it will now be apparent to those skilled in the art that numerous modifications can be made therein without departing from the scope of the invention as defined in the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practised otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

We claim:

1. A layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

2. Layer configuration according to claim 1, wherein said coadsorber is an ortho-dihydroxy-benzene compound.

3. Layer configuration according to claim 2, wherein said benzene compound with a nitrile group substituted on the same benzene ring as said ortho-dihydroxy-groups.

4. Layer configuration according to claim 1, wherein said coadsorber is selected from the group consisting of 2,3-dihydroxy-benzonitrile, 3,4-dihydroxy-benzonitrile, 3,4,5-trihydroxy-benzonitrile, 3,4-dihydroxy-4′-cyano-benzophenone, 4-nitro-catechol, (3,4-dihydroxy-phenyl)methyl-sulphone, 1,2-dihydroxy-anthraquinone, 3,4-dihydroxy-anthraquinone-2-sulphonic acid, 4,5-dihydroxy-benzene-1,3-disulphonic acid, 6,7-dihydroxy-naphthalene-2-sulphonic acid, 3,4-dihydroxy-benzoic acid and catechol.

5. Layer configuration according to claim 1, wherein said coadsorber is selected from the group consisting of 3,4-dihydroxy-benzonitrile, 3,4,5-trihydroxy-benzonitrile, 1,2-dihydroxy-anthraquinone, (3,4-dihydroxy-phenyl)methylsulphone, 4,5-dihydroxy-benzene-1,3-disulphonic acid and catechol.

6. Layer configuration according to claim 1, wherein said cationic spectral sensitizer is a cyanine dye.

7. A photovoltaic device comprising a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

8. A solar cell comprising a layer configuration comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor.

9. A process for preparing a layer configuration, comprising a layer of a nano-porous n-type metal oxide semiconductor with a band-gap of greater than 2.7 eV, an adsorbed cationic spectral sensitizer and a coadsorber capable of enhancing the adsorption of a cationic spectral sensitizer on a n-type metal oxide semiconductor, comprising the steps of: providing a layer of a nano-porous n-type metal oxide semiconductor with a band-gap of greater than 2.7 eV, adsorbing a coadsorber on said nano-porous n-type metal oxide semiconductor layer and adsorbing a cationic spectral sensitizer on said nano-porous n-type metal oxide semiconductor layer.

10. Process according to claim 9, wherein said adsorption of said cationic spectral sensitizer on said nano-porous n-type metal oxide semiconductor layer is carried out simultaneously with said adsorption of said coadsorber on said nano-porous n-type metal oxide semiconductor layer.

11. Process according to claim 9, wherein said adsorption of said cationic spectral sensitizer on said nano-porous n-type metal oxide semiconductor layer is carried out after said adsorption of said coadsorber on said nano-porous n-type metal oxide semiconductor layer.
